(19) United States
(12) Patent Application Publication
(10) Pub. No.: US 2016/0254816 A1
(43) Pub. Date: Sep. 1, 2016

(54) VOLTAGE CONTROLLED OSCILLATOR

(71) Applicant: KABUSHIKI KAISHA TOSHIBA, Tokyo (JP)

(72) Inventor: Hiroyuki KOBAYASHI, Yokohama Kanagawa (JP)

(21) Appl. No.: 14/836,879

(22) Filed: Aug. 26, 2015

(30) Foreign Application Priority Data
Feb. 26, 2015 (JP) 2015-037079

(51) Int. Cl. H03L 1/02; H03B 5/12

(52) U.S. Cl. CPC H03L 1/02; H03B 5/1228; H03B 5/1212; H03B 5/124

(57) ABSTRACT

A stabilized oscillator includes a first transistor, a second transistor, a load, an amplifier, and an oscillator using an LC resonant circuit. The first transistor includes a source terminal connected to a first reference voltage line, a gate terminal connected to a first node, and a drain terminal connected to a second node. The second transistor includes a source terminal connected to the first reference voltage line, a gate terminal connected to the first node, and a drain terminal connected to a third node. The load is connected between the third node and a second reference voltage line. The amplifier has an output terminal connected to the first node, a first input terminal connected to the second node, and a second input terminal connected to the third node. The oscillator is connected between the second node and the second reference voltage line.

### CROSS-REFERENCE TO RELATED APPLICATION

This application is based upon and claims the benefit of priority from Japanese Patent Application No. 2015-037079, filed Feb. 26, 2015, the entire contents of which are incorporated herein by reference.

### FIELD

Embodiments described herein relate generally to voltage controlled oscillators.

### BACKGROUND

In the related art, a voltage control oscillator (VCO) provided with a transistor has been used as a drive current source. In such a VCO, since a drive current commensurate with the gate voltage of the transistor flows through the VCO, if noise is in the gate voltage, phase noise is generated in the output of the VCO.

Thus, in order to reduce noise in the gate voltage, a circuit that applies a gate voltage via a low-pass filter (LPF) is proposed. However, since a large LPF is required to reduce the phase noise of the VCO, the circuit size is undesirably increased. Moreover, it is difficult to reduce phase noise caused by fluctuations in a power-supply voltage.

A VCO that detects the output amplitude of the VCO with an amplitude detector and controls the gate voltage such that the output amplitude becomes constant in order to reduce phase noise caused by fluctuations in a power-supply voltage has been proposed, but this VCO requires a large LPF and the amplitude detector becomes a load of a non-negligible size for the VCO, which undesirably degrades the performance of the VCO.

### DESCRIPTION OF THE DRAWINGS

FIG. 1 is a schematic diagram depicting a voltage controlled oscillator according to a first embodiment.

FIG. 2 is a diagram depicting the operation of an amplifier.

FIG. 3 is a diagram depicting an example of an oscillator of FIG. 1.

FIG. 4 is a diagram depicting an example of the oscillator of FIG. 1.

FIG. 5 is a diagram depicting an example of a load of FIG. 1.

FIG. 6 is a diagram depicting an example of the load of FIG. 1.

FIG. 7 is a diagram depicting an example of the load of FIG. 1.

FIG. 8 is a schematic diagram depicting a modified example of the voltage controlled oscillator of FIG. 1.

FIG. 9 is a diagram depicting an example of the voltage controlled oscillator of FIG. 8.

FIG. 10 is a schematic diagram depicting a voltage controlled oscillator according to a second embodiment.

FIG. 11 is a diagram depicting an example of a first transistor of FIG. 10.

FIG. 12 is a diagram explaining calibration.

FIG. 13 is a schematic diagram depicting a voltage controlled oscillator according to a third embodiment.

### DETAILED DESCRIPTION

Embodiments provide a voltage controlled (i.e., stabilized) oscillator in which phase noise is reduced.

In general, according to one embodiment, a stabilized oscillator includes a first transistor, a second transistor, a load, an amplifier, and an oscillator using an LC resonant circuit. The first transistor includes a source terminal connected to a first reference voltage line, a gate terminal connected to a first node, and a drain terminal connected to a second node. The second transistor includes a source terminal connected to the first reference voltage line, a gate terminal connected to the first node, and a drain terminal connected to a third node. The load has one end connected to the third node and another end connected to a second reference voltage line. The amplifier has an output terminal connected to the first node, a first input terminal connected to the second node, and a second input terminal connected to the third node. The oscillator has one end connected to the second node and another end connected to the second reference voltage line.

Hereinafter, embodiments are described with reference to the drawings.

### FIRST EMBODIMENT

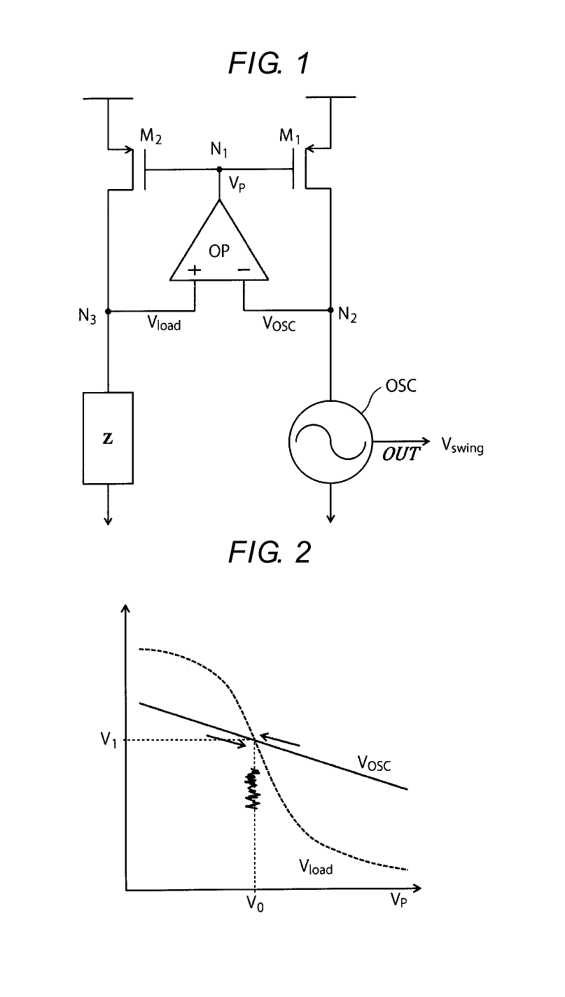

First, a VCO according to a first embodiment is described with reference to FIGS. 1 through 9. FIG. 1 is a schematic diagram depicting the VCO according to this embodiment. As depicted in FIG. 1, this VCO includes a first transistor M₁, a second transistor M₂, a load Z, an amplifier OP, and an oscillator OSC.

The first transistor M₁ is a P-channel MOS transistor (hereinafter referred to as a “PMOS”) and has a source terminal connected to a power-supply line (a first reference voltage line), a gate terminal connected to a first node N₁, and a drain terminal connected to a second node N₂.

The second transistor M₂ is a PMOS and includes a source terminal connected to the power-supply line (the first reference voltage line), a gate terminal connected to the first node N₁, and a drain terminal connected to a third node N₃.

The load Z has one end connected to the third node N₃ and the other end connected to a grounding conductor (a second reference voltage line).

The amplifier OP is an operational amplifier and includes an output terminal connected to the first node N₁, a negative input terminal (a first input terminal) connected to the second node N₂, and a positive input terminal (a second input terminal) connected to the third node N₃.

The oscillator OSC is an oscillator that includes an LC resonant circuit and has one end connected to the second node N₂ and the other end connected to the grounding conductor (the second reference voltage line). The oscillator OSC is driven by a current which is supplied from the first transistor M₁ and outputs an oscillation signal from an output terminal OUT.

Hereinafter, the voltage at the first node N₁ is referred to as V_{P}, the voltage at the second node N₂ is referred to as V_{OSC}, and the voltage at the third node N₃ is referred to as V_{load}. Moreover, it is assumed that the oscillation signal is a voltage V_{swing}.

FIG. 2 is a diagram depicting the relationship among V_{P}, V_{OSC}, and V_{load}. In FIG. 2, the solid line indicates V_{OSC} and the broken line indicates V_{load}. If a load whose current-voltage characteristics are close to a linear shape is selected, as depicted in FIG. 2, when V_{P} rises, V_{OSC} gradually drops and V_{load} sharply drops. Moreover, when V_{P} drops, V_{OSC} gradually rises and V_{load} sharply rises. This is because the impedance characteristics of the oscillator OSC are close to the impedance characteristics of a diode-connected MOS. Therefore, when V_{P} is a predetermined voltage V₀ (V_{P}=V₀) V_{OSC} and V_{load} coincide with each other at a predetermined voltage V₁ (V_{OSC}=V_{load}=V₁).

In this embodiment, since the second node N₂ is connected to the negative input terminal of the amplifier OP and the third node N₃ is connected to the positive input terminal of the amplifier OP, the second node N₂ and the third node N₃ are virtually connected. That is, the amplifier OP controls the output voltage V_{P} such that V_{OSC} and V_{load} coincide with each other. Specifically, the amplifier OP decreases V_{P} if V_{OSC}>V_{load} (V_{P}>V₀) and increases V_{P} if V_{OSC}<V_{load} (V_{P}<V₀). As a result, V_{P} is stabilized at V₀ and V_{OSC} and V_{load} are stabilized at V₁.

Owing to such a configuration, in the VCO according to this embodiment, even when noise is generated in the voltage V_{P} at the gate terminal of the first transistor M₁, the voltage V_{OSC} which is applied to the oscillator OSC becomes constant. Therefore, it is possible to reduce the phase noise of the oscillator OSC without connecting an extraneous load to the output side of the oscillator OSC.

Moreover, the output amplitude of the oscillator OSC (the amplitude of V_{swing}) is proportional to V_{OSC}. Therefore, because of V_{OSC} becoming constant, it is possible to stabilize the output amplitude of the oscillator OSC.

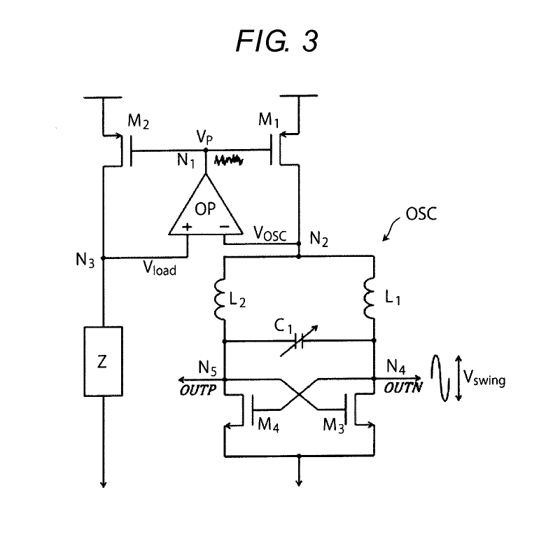

FIG. 3 is a diagram depicting an example of the oscillator OSC of FIG. 1. The oscillator OSC of FIG. 3 includes a first inductor L₁, a second inductor L₂, a first variable capacitance C₁, a third transistor M₃, and a fourth transistor M₄.

The first inductor L₁ has one end connected to the second node N₂ and the other end connected to a fourth node N₄. The fourth node N₄ is connected to an output terminal OUTN. The output terminal OUTN outputs the voltage at the fourth node N₄.

The second inductor L₂ has one end connected to the second node N₂ and the other end connected to a fifth node N₅. The fifth node N₅ is connected to an output terminal OUTP. The output terminal OUTP outputs the voltage at the fifth node N₅.

In FIG. 3, the one end of the first inductor L₁ and the one end of the second inductor L₂ form one end of the oscillator OSC.

The first variable capacitance C₁ has one end connected to the fourth node N₄ and the other end connected to the fifth node N₅. The first inductor L₁, the second inductor L₂, and the first variable capacitance C₁ form an LC resonant circuit. Moreover, though not depicted in the drawing, to the first variable capacitance C₁, a control circuit that controls a capacitance value is connected. By making the control circuit change the capacitance value of the first variable capacitance C₁, the oscillation frequency of the oscillator OSC is controlled.

The third transistor M₃ is an N-channel MOS transistor (hereinafter referred to as an “NMOS”) and has a source terminal connected to the grounding conductor (the second reference voltage line), a gate terminal connected to the fifth node N₅, and a drain terminal connected to the fourth node N₄.

The fourth transistor M₄ is an NMOS and includes a source terminal connected to the grounding conductor (the second reference voltage line), a gate terminal connected to the fourth node N₄, and a drain terminal connected to the fifth node N₅.

In FIG. 3, the source terminal of the third transistor M₃ and the source terminal of the fourth transistor M₄ form the other end of the oscillator OSC.

Owing to such a configuration, the oscillator OSC of FIG. 3 generates a differential output of the voltage V_{swing} from the output terminals OUTN and OUTP. In the oscillator OSC of FIG. 3, V_{swing} is a sinusoidal wave being displaced with V_{OSC} at the center thereof. Therefore, by keeping V_{OSC} constant, it is possible to reduce the phase noise of the oscillator OSC and stabilize the output amplitude.

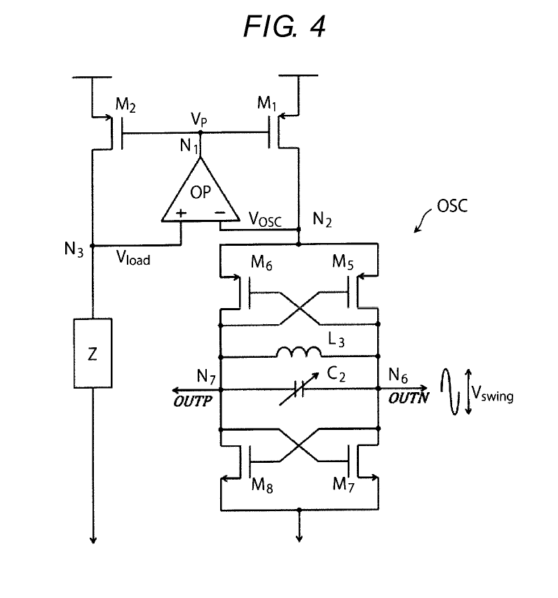

FIG. 4 is a diagram depicting another example of the oscillator OSC of FIG. 1. The oscillator OSC of FIG. 4 includes a third inductor L₃, a second variable capacitance C₂, a fifth transistor M₅, a sixth transistor M₆, a seventh transistor M₇, and an eighth transistor M₈.

The third inductor L₃ has one end connected to a sixth node N₆ and the other end connected to a seventh node N₇. The sixth node N₆ is connected to an output terminal OUTN. The output terminal OUTN outputs the voltage at the sixth node N₆. The seventh node N₇ is connected to an output terminal OUTP. The output terminal OUTP outputs the voltage at the seventh node N₇.

The second variable capacitance C₂ has one end connected to the sixth node N₆ and the other end connected to the seventh node N₇. The third inductor L₃ and the second variable capacitance C₂ form an LC resonant circuit. Moreover, though not depicted in the drawing, to the second variable capacitance C₂, a control circuit that controls a capacitance value is connected. By making the control circuit change the capacitance value of the second variable capacitance C₂, the oscillation frequency of the oscillator OSC is controlled.

The fifth transistor M₅ is a PMOS and includes a source terminal connected to the second node N₂, a gate terminal connected to the seventh node N₇, and a drain terminal connected to the sixth node N₆.

The sixth transistor M₆ is a PMOS and includes a source terminal connected to the second node N₂, a gate terminal connected to the sixth node N₆, and a drain terminal connected to the seventh node N₇.

In FIG. 4, the source terminal of the fifth transistor M₅ and the source terminal of the sixth transistor M₆ form one end of the oscillator OSC.

The seventh transistor M₇ is an NMOS and has a source terminal connected to the grounding conductor (the second reference voltage line), a gate terminal connected to the seventh node N₇, and a drain terminal connected to the sixth node N₆.

The eighth transistor M₈ is an NMOS and has a source terminal connected to the grounding conductor (the second reference voltage line), a gate terminal connected to the sixth node N₆, and a drain terminal connected to the seventh node N₇.

In FIG. 4, the source terminal of the seventh transistor M₇ and the source terminal of the eighth transistor M₈ form the other end of the oscillator OSC.

Owing to such a configuration, the oscillator OSC of FIG. 4 produces a differential output of the voltage V_{swing} from the output terminals OUTN and OUTP. In the oscillator OSC of FIG. 4, V_{swing} is a sinusoidal wave proportional to V_{OSC}. Therefore, by keeping V_{OSC} constant, it is possible to reduce the phase noise of the oscillator OSC and stabilize the output amplitude.

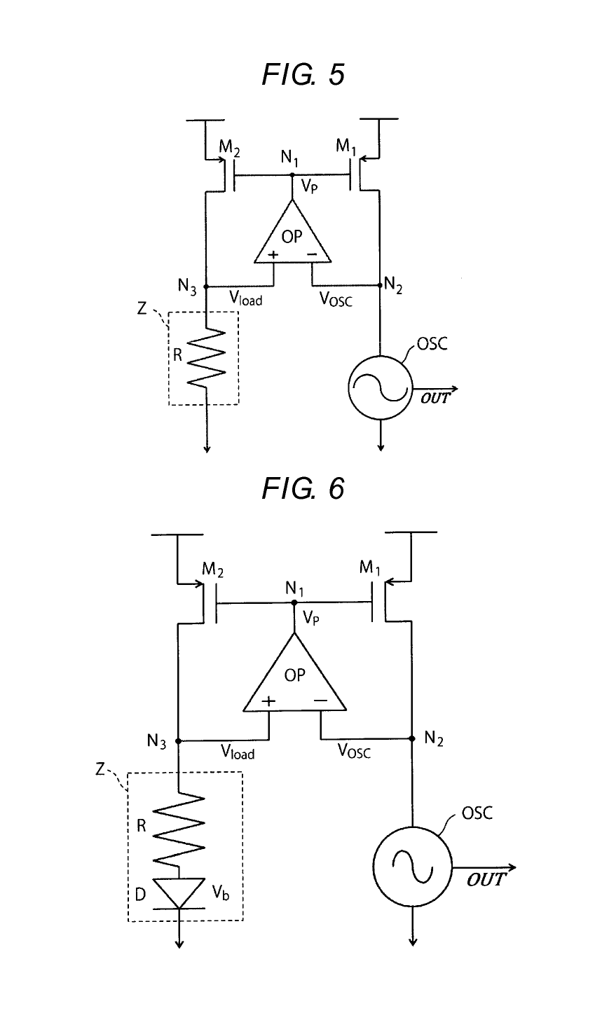

FIG. 5 is a diagram depicting an example of the load Z of FIG. 1. The load Z of FIG. 5 includes a resistor R.

The resistor R has one end connected to the third node N₃ and the other end connected to the grounding conductor (the second reference voltage line). In FIG. 5, one end of the load Z is the one end of the resistor R and the other end of the load Z is the other end of the resistor R. As described above, the resistor R may be used as the load Z.

FIG. 6 is a diagram depicting another example of the load Z of FIG. 1. The load Z of FIG. 6 includes a resistor R and a diode D which are connected in series.

The resistor R has one end connected to the third node N₃ and the other end connected to the anode terminal of the diode D. The diode D includes the anode terminal connected to the other end of the resistor R and a cathode terminal connected to the grounding conductor (the second reference voltage line). In FIG. 6, one end of the load Z is the one end of the resistor R and the other end of the load Z is the cathode terminal of the diode D.

In general, under constant operating current conditions, the oscillator OSC has the following temperature dependence: the higher the temperature, the smaller the output amplitude. Therefore, if the load is a resistor, the oscillation amplitude is decreased depending on the temperature. However, as depicted in FIG. 6, by using the diode D as the load Z, it is possible to reduce the temperature dependence of the oscillator OSC.

This is because the voltage V_{b} of the diode D decreases with an increase in the temperature. If the voltage V_{b} of the diode D decreases when the temperature is high, a voltage (V_{load}−V_{b}) which is applied to the resistor R rises and a current flowing through the resistor R increases. Accordingly, a current flowing through the oscillator OSC also increases.

Thus, when the temperature is high, the output amplitude of the oscillator OSC is decreased due to the temperature dependence and is increased due to an increase in the current. As a result, these effects cancel each other out and the temperature dependence of the oscillator OSC is reduced.

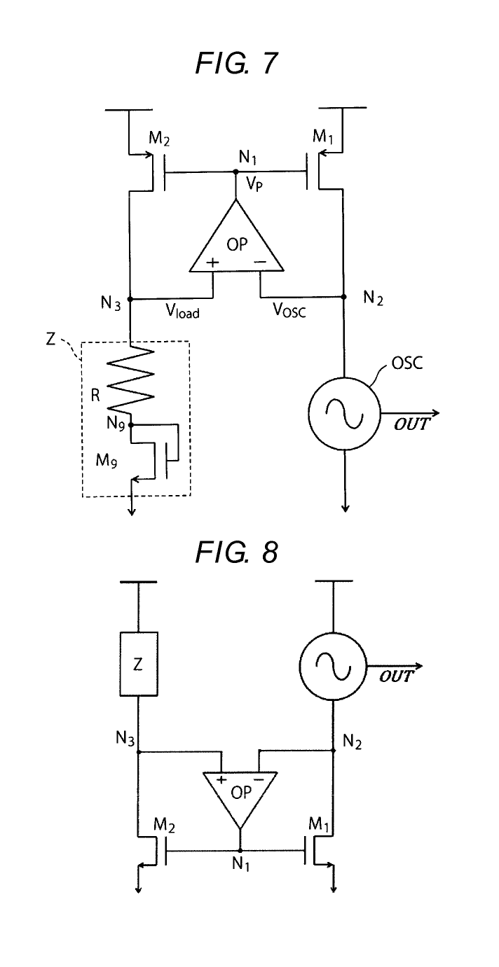

FIG. 7 is a diagram depicting another example of the load Z of FIG. 1. The load Z of FIG. 7 includes a resistor R and a ninth transistor M₉ which are connected in series.

The resistor R has one end connected to the third node N₃ and the other end connected to a ninth node N₉. The ninth transistor M₉ is an NMOS and has a source terminal connected to a grounding conductor and a gate terminal and a drain terminal which are connected to the ninth node N₉. That is, the ninth transistor M₉ is diode-connected.

The drain-source voltage of the ninth transistor M₉ decreases with an increase in the temperature. Therefore, even with the load Z of FIG. 7, as is the case with FIG. 6, it is possible to reduce the temperature dependence of the oscillator OSC.

In the above description, each of the first transistor M1 and the second transistor M₂ is a PMOS, but each of the first transistor M₁ and the second transistor M₂ may be an NMOS. FIG. 8 is a schematic diagram depicting a VCO that is obtained when each of the first transistor M₁ and the second transistor M₂ is an NMOS.

The first transistor M₁ is an NMOS and includes a source terminal connected to the grounding conductor (the first reference voltage line), a gate terminal connected to the first node N₁, and a drain terminal connected to the second node N₂.

The second transistor M₂ is an NMOS and includes a source terminal connected to the grounding conductor (the first reference voltage line), a gate terminal connected to the first node N₁, and a drain terminal connected to the third node N₃.

The load Z has one end connected to the third node N₃ and the other end connected to the power-supply line (the second reference voltage line).

The amplifier OP is an operational amplifier and includes an output terminal connected to the first node N₁, a negative input terminal (a first input terminal) connected to the second node N₂, and a positive input terminal (a second input terminal) connected to the third node N₃.

The oscillator OSC is an oscillator using an LC resonant circuit and has one end connected to the second node N₂ and the other end connected to the power-supply line (the second reference voltage line). The oscillator OSC is driven by a current which is supplied from the first transistor M₁ and outputs an oscillation signal from the output terminal OUT.

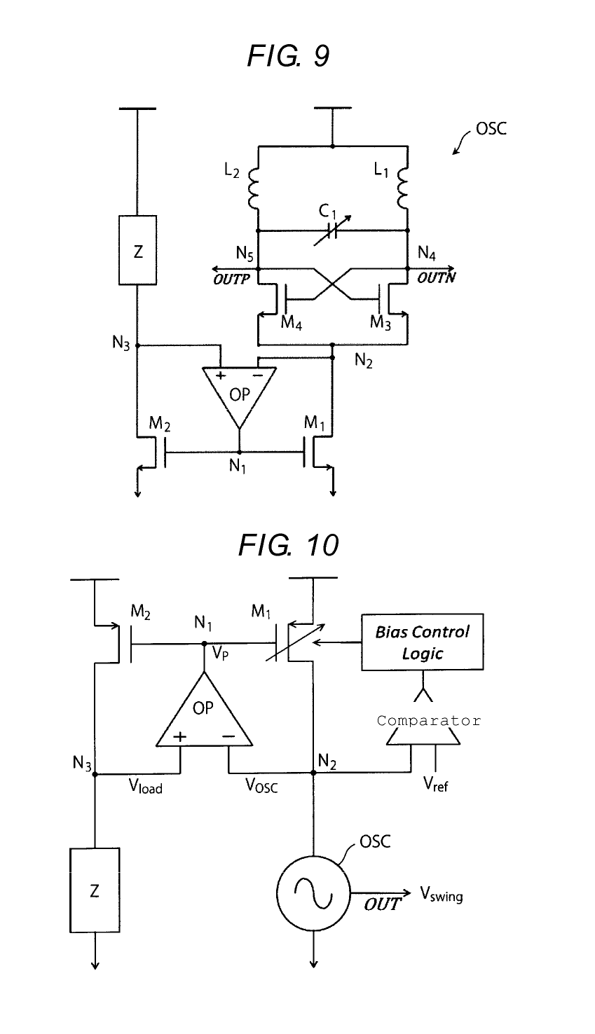

Owing to such a configuration, as described above, it is possible to reduce the phase noise of the oscillator OSC and stabilize the output amplitude. When the oscillator OSC of FIG. 3 is applied to the VCO of FIG. 8, as depicted in FIG. 9, it is simply necessary to replace the position of one end of the oscillator OSC with the position of the other end thereof and then connect the oscillator OSC to the VCO of FIG. 8.

That is, the oscillator OSC simply has to be connected to the VCO of FIG. 8 in such a way that the source terminal of the third inductor M₃ and the source terminal of the fourth inductor M₄ form one end of the oscillator OSC and one end of the first inductor L₁ and one end of the second inductor L₂ form the other end of the oscillator OSC. The same is applicable to the oscillator OSC of FIG. 4.

### SECOND EMBODIMENT

Next, a VCO according to a second embodiment is described with reference to FIGS. 10 to 12. FIG. 10 is a schematic diagram depicting the VCO according to this embodiment. As depicted in FIG. 10, the VCO according to this embodiment further includes a comparator and a bias control circuit (Bias Control Logic).

The comparator has a first input terminal connected to the second node N₂ and a second input terminal connected to a reference voltage source (not depicted in the drawing). The comparator compares V_{OSC} input from the first input terminal and a reference voltage V_{ref} input from the second input terminal and outputs a signal in accordance with the comparison result.

The bias control circuit is a logic circuit and receives the output signal of the comparator which is input to the bias control circuit. The bias control circuit controls the size of the first transistor M₁ in such away that V_{OSC} and V_{ref} become close to each other based on the comparison result obtained by the comparator. The bias control circuit controls the size of the first transistor M₁ (performs calibration) at the time of start of the VCO.

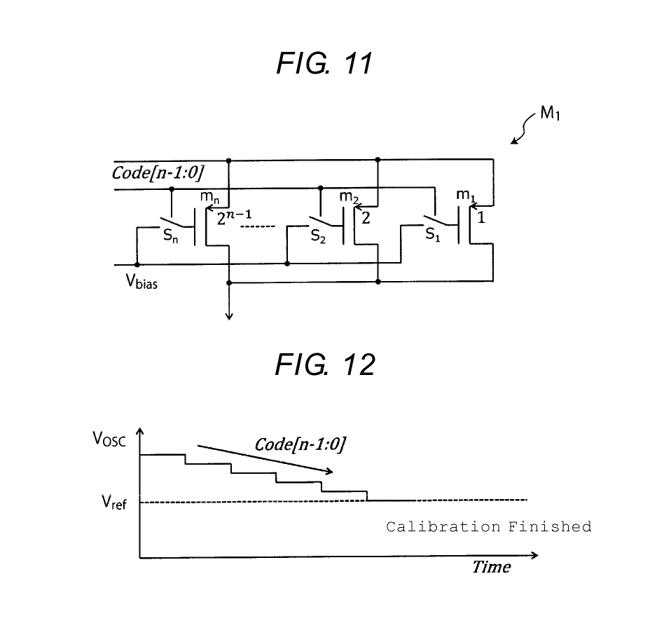

FIG. 11 is a diagram depicting an example of the first transistor M₁ according to this embodiment. The first transistor M₁ of FIG. 11 is formed of n transistors m₁ to mₙ which are connected in parallel and have different sizes. Each of the transistors m₁ to mₙ is a PMOS. Hereinafter, it is assumed that a transistor m_{X} is a transistor having the X-th smallest size in the transistors m₁ to mₙ.

In FIG. 11, the transistor m_{X} has a source terminal connected to the power-supply line and a drain terminal connected to the second node N₂ and is 2^{x-1} times as large as the transistor m₁. The gate terminal of the transistor m_{X} is connected to the first node N₁ via a switch S_{X}.

The opening and closing of the switch S_{X} is controlled by a control signal (Code [n-1:0]) from the bias control circuit. When the switch S_{X} is turned on by the control signal, the gate terminal of the transistor m_{X} and the first node N₁ are connected to each other, a bias voltage V_{bias}(=V_{P}) is applied to the gate terminal, and the transistor m_{X} is turned on. Then, one or a plurality of transistors m_{X} which have been turned on function as the first transistor M₁ having the total size of the transistors m_{X} which have been turned on.

As described above, by selecting the transistor m_{X} which is turned on by the control signal, the bias control circuit controls the size of the first transistor M₁. If the first transistor M₁ is formed of n transistors m_{X}, the size of the first transistor M₁ is controlled in 2^{N}−1 levels.

FIG. 12 is a diagram explaining calibration which is performed by the bias control circuit. As depicted in FIG. 12, the bias control circuit sets the size of the first transistor M₁ to the maximum size and the comparator compares V_{OSC} and V_{ref}. If V_{OSC} is higher than V_{ref}, the bias control circuit sets the size of the first transistor M₁ to a size smaller than the current size by 1 level, and the comparator compares V_{OSC} and V_{ref} again. The bias control circuit repeats such processing until V_{OSC} and V_{ref} coincide with each other or V_{OSC} becomes lower than V_{ref}. As a result, the size of the first transistor M₁ is controlled in such a way that V_{OSC} and V_{ref} are close to each other. After the completion of calibration, the comparator and the bias control circuit stop the operations thereof.

As described above, the output amplitude of the oscillator OSC varies depending on the temperature. Therefore, for example, there is a possibility that the output amplitude is decreased when the temperature is high and an intended output amplitude is not obtained. However, the VCO according to this embodiment controls the size of the first transistor M₁ in such a way that V_{OSC} and V_{ref} are close to each other at the time of start. As a result, for example, when the temperature is high, the size of the first transistor M₁ is set as a larger size, the current of the oscillator OSC increases, and the output amplitude is increased. As described above, by controlling the size of the first transistor M₁, it is possible to adjust the output amplitude of the VCO to an intended magnitude.

Moreover, since the comparator and the bias control circuit are turned off during the operation of the VCO, the comparator and the bias control circuit do not contribute to noise. Therefore, it is possible to control the output amplitude while reducing the phase noise of the VCO.

### THIRD EMBODIMENT

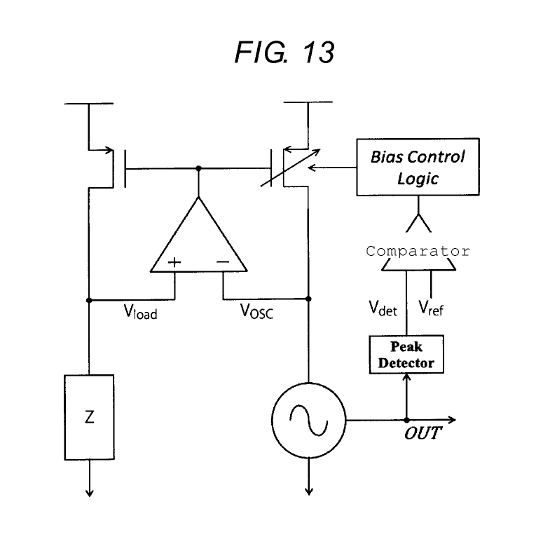

Next, a VCO according to a third embodiment is described with reference to FIG. 13. FIG. 13 is a schematic diagram depicting the VCO according to this embodiment. As depicted in FIG. 13, the VCO according to this embodiment further includes an amplitude detector (Peak Detector).

The amplitude detector is connected to the output terminal OUT, receives an output voltage V_{swing} of the oscillator OSC which is input thereto, and detects an output amplitude (the amplitude of V_{swing}).

The comparator compares the output amplitude V_{det} detected by the amplitude detector and the reference voltage V_{ref} and outputs a comparison result.

The bias control circuit receives the comparison result input from the comparator and controls the size of the first transistor M₁ (performs calibration) in such a way that the output amplitude V_{det} and the reference voltage V_{ref} are close to each other. Calibration is performed at the time of start of the VCO, and, after the completion of calibration, the amplitude detector stops the operation thereof. As is the case with the second embodiment, calibration is performed by searching for a size in which V_{det} and V_{ref} are close to each other while gradually reducing the size of the first transistor M₁.

As described above, by controlling the size of the first transistor M₁, the VCO according to this embodiment may adjust the output amplitude of the VCO to an intended magnitude. Moreover, since the amplitude detector is turned off during the operation of the VCO, the amplitude detector does not contribute to noise. Furthermore, unlike the existing method, since there is no need to take noise which is generated in the amplitude detector into consideration, it is possible to reduce the size of an element forming the circuit so that the element is too small to be visible as a load of the VCO. This makes it possible to control the output amplitude while reducing the phase noise of the VCO.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A stabilized oscillator comprising:
a first transistor that includes a source terminal connected to a first reference voltage line, a gate terminal connected to a first node, and a drain terminal connected to a second node;
a second transistor that includes a source terminal connected to the first reference voltage line, a gate terminal connected to the first node, and a drain terminal connected to a third node;
a load that has one end connected to the third node and another end connected to a second reference voltage line;
an amplifier that has an output terminal connected to the first node, a first input terminal connected to the second node, and a second input terminal connected to the third node; and
an oscillator that includes an LC resonant circuit, the oscillator having one end connected to the second node and another end connected to the second reference voltage line.

2. The oscillator according to claim 1, wherein the oscillator includes
a first inductor having one end connected to the second node and another end connected to a fourth node,
a second inductor having one end connected to the second node and another end connected to a fifth node,
a variable capacitance having one end connected to the fourth node and another end connected to the fifth node,
a third transistor including a source terminal connected to the second reference voltage line, a gate terminal connected to the fifth node, and a drain terminal connected to the fourth node, and
a fourth transistor including a source terminal connected to the second reference voltage line, a gate terminal connected to the fourth node, and a drain terminal connected to the fifth node.

3. The oscillator according to claim 1, wherein each of the first transistor and the second transistor is a P-channel MOS transistor.

4. The oscillator according to claim 3, wherein each of the third transistor and the fourth transistor is an N-channel MOS transistor.

5. The oscillator according to claim 1, wherein the oscillator includes
a first inductor having one end connected to the first reference voltage line and another end connected to a fourth node,
a second inductor having one end connected to the first reference voltage line and another end connected to a fifth node,
a variable capacitance having one end connected to the fourth node and another end connected to the fifth node,
a third transistor that includes a source terminal connected to the second node, a gate terminal connected to the fifth node, and a drain terminal connected to the fourth node, and
a fourth transistor that includes a source terminal connected to the second node, a gate terminal connected to the fourth node, and a drain terminal connected to the fifth node.

6. The oscillator according to claim 1, wherein the load includes a resistor.

7. The oscillator according to claim 1, wherein the load includes a resistor and a diode that are connected in series.

8. The oscillator according to claim 1, wherein the load includes a resistor and a transistor that are connected in series.

9. The oscillator according to claim 1, further comprising:
a comparator that compares a voltage at the second node and a reference voltage; and
a control circuit that controls a size of the first transistor based on a comparison result obtained by the comparator.

10. The oscillator according to claim 9, wherein the control circuit controls the size so that the voltage at the second node and the reference voltage are close to each other.

11. The oscillator according to claim 1, further comprising:
an amplitude detector that detects an output amplitude of the oscillator;
a comparator that compares the output amplitude and a reference voltage; and
a control circuit that controls a size of the first transistor based on a comparison result obtained by the comparator.

12. A stabilized oscillator comprising
first and second transistors, each having a gate, source and drain, the gates of the first and second transistors connected to each other and the sources of the first and second transistors connected to each other and to a first reference voltage;
a high-gain amplifier having a positive input, a negative input, and an output, the amplifier output connected to the gates of the first and second transistors, the positive amplifier input connected to the drain of the second transistor, the negative amplifier input connected to the drain of the first transistor;
an oscillator connected between a second reference voltage line and the drain of the first transistor to receive current from the first transistor; and
a load connected between the second reference voltage line and the drain of the second transistor to receive current from the second transistor,
wherein the drain voltage of the second transistor coincides with the drain voltage of the first transistor.

13. The stabilized oscillator according to claim 12, wherein the load includes a resistor connected between the second reference voltage and the drain of the second transistor.

14. The stabilized oscillator according to claim 12, wherein the load includes a resistor and a diode connected in series and between the second reference voltage and the drain of the second transistor.

15. The stabilized oscillator according to claim 12, wherein the load includes a resistor and a diode-connected transistor connected in series and between the second reference voltage and the drain of the second transistor.

16. The stabilized oscillator according to claim 12, wherein the first transistor is implemented from a plurality of transistors of different sizes and arranged in parallel, the stabilized oscillator further comprising:
a comparator that compares the drain voltage of the first transistor to a third reference voltage line and provide comparison results at an output; and
a bias control logic that receives the comparator output and enables one or more transistors among the plurality of transistors in order to set the size of the first transistor based on the comparator output.

17. The stabilized oscillator according to claim 16, wherein the bias control logic generates a code that selects the one or more transistors among the plurality of transistors.

18. The stabilized oscillator according to claim 12, wherein the first transistor is implemented from a plurality of transistors of different sizes and arranged in parallel, the stabilized oscillator further comprising:
a peak detector that generates a voltage output when the oscillator output is at a maximum voltage;
a comparator that compares the voltage output of the peak detector to a third reference voltage line and provides comparison results at an output; and
a bias control logic that receives the comparator output and enables one or more transistors among the plurality of transistors in order to set the size of the first transistor.

19. A method of stabilizing an oscillator, the method comprising:
providing via a first path a voltage and a current to the oscillator, the oscillator generating an oscillation signal at an output terminal, the oscillation signal having a particular voltage swing;
providing via a second path a voltage and current to a load, wherein the oscillator voltage coincides with the load voltage without the load being connected to the oscillator; and
stabilizing the voltage to the load so that the voltage swing of the oscillation signal is stabilized.

20. The method according to claim 19, wherein the load is temperature stabilized.
